(19) United States
(12) Patent Application Publication
(10) Pub. No.: US 2026/0250879 A1
(43) Pub. Date: Aug. 27, 2026

(54) EPITAXIAL GROWTH METHOD

(71) Applicant: SK SILTRON CO., LTD., Gyeongsangbuk-do (KR)

(72) Inventors: Tae Hyeok KWAK, Gyeongsangbuk-do (KR); Jun Han Lee, Gyeongsangbuk-do (KR); Seung Jin Park, Gyeongsangbuk-do (KR); Ji Won Song, Gyeongsangbuk-do (KR)

(21) Appl. No.: 19/547,929

(22) Filed: Feb. 24, 2026

(30) Foreign Application Priority Data
Feb. 26, 2025 (KR) 10-2025-0025135
Feb. 10, 2026 (KR) 10-2026-0026673

(51) Int. Cl. C30B 25/16

(52) U.S. Cl. CPC C30B 25/16

(57) ABSTRACT

Disclosed is an epitaxial growth method capable of measuring thickness differences of an epitaxial layer deposited on a wafer and varying the position of a reflector based thereon to control the amount of heat supplied to the wafer, thereby depositing an epitaxial layer having a uniform thickness on the surface of the wafer. The distance between the wafer and the reflector is adjusted to control the amount of heat supplied to the wafer such that light concentrated on a radial middle part of the wafer at which temperatures are relatively high is blocked or dispersed to uniformly supply heat to the surface of the epitaxial wafer, thereby improving uniformity in the thickness of the epitaxial layer.

### CROSS REFERENCE TO RELATED APPLICATION

This application claims priority under 35 U.S.C. § 119 to Korean Patent Application Nos. 10-2025-0025135, filed Feb. 26, 2025, and 10-2026-0026673, filed Feb. 10, 2026, which is hereby incorporated in its entirety by references as if fully set forth herein.

### TECHNICAL FIELD

Embodiments relate to an epitaxial growth method, and more particularly to an epitaxial growth method capable of measuring changes in the thickness of an epitaxial layer deposited on a wafer, varying the position or shape of a reflector based thereon, and controlling the amount of heat supplied to the wafer, thereby achieving a more uniform thickness of the epitaxial layer deposited on the surface of the wafer.

### BACKGROUND

A wafer, which is used as a material in semiconductor device manufacturing, is produced through a slicing process of thinly cutting a single-crystal silicon ingot in the form of a wafer, a lapping process of improving flatness of the wafer while polishing the wafer to a desired thickness, an etching process of removing wafer damage, a polishing process of performing mirror finishing and planarization of the wafer, and a cleaning process of removing contaminants from the surface of the wafer.

An epitaxial wafer is produced by forming a thin epitaxial layer on a polished wafer using chemical vapor deposition in a chamber heated to a temperature of 1000° C. or higher. The growth of the epitaxial layer is closely related to temperature. Higher growth temperatures result in faster epitaxial layer growth, whereas lower growth temperatures cause slower epitaxial layer growth. Therefore, when growing an epitaxial layer on a wafer, heat must be uniformly provided across the entire surface of the wafer.

Since the growth rate of an epitaxial layer grown on a silicon wafer is affected by temperature, controlling the temperature distribution across the silicon wafer in a diameter direction is crucial to improve the thickness uniformity of the epitaxial layer. In order to improve the thickness uniformity of the epitaxial layer, deviation in the temperature distribution across the wafer in the diameter direction must be small. To this end, a vapor deposition apparatus may include a reflector configured to provide uniform temperature to a wafer located in a reactor.

An epitaxial wafer manufacturing method capable of achieving a uniform resistance value of an epitaxial wafer is disclosed in Korean Patent Application Publication No. 10-2024-0115127.

FIG. 1 is a flowchart showing the steps of a conventional epitaxial manufacturing method.

As shown in FIG. 1, the conventional epitaxial manufacturing method includes a step of loading a silicon substrate on a susceptor in a reaction chamber (S1), a step of performing pre-baking to remove a natural oxide layer from the silicon substrate (S2), a step of controlling the flow rate of lower gas so as to be 25% or less of the flow rate of upper gas based on the susceptor during the pre-baking step (S3), a step of allowing a first set time to elapse (S4), a step of depositing an epitaxial layer while controlling the flow rate of the lower gas so as to be 25% or less of the flow rate of the upper gas based on the susceptor (S5 and S6), a step of allowing a second set time to elapse (S7), a cooling step (S8), and a step of unloading an epitaxial wafer (S9).

In the conventional epitaxial wafer manufacturing method, the ratio of the flow rate of the lower transport gas to the flow rate of the upper transport gas based on the susceptor is controlled to 25% or less in the deposition step. This prevents a dopant volatilized from a rear surface of the silicon substrate seated on the susceptor from flowing to an upper surface of an edge of the silicon substrate, thereby achieving a uniform resistance value of the epitaxial wafer.

However, this technology cannot resolve the issue of uneven epitaxial layer thickness due to temperature differences across the surface of the wafer. This presents the difficulty of uniformly supplying heat to the surface of the wafer.

### SUMMARY

Embodiments solve the above problems.

Embodiments provide an epitaxial growth method capable of improving the uniformity of the thickness of an epitaxial layer by uniformly supplying heat to the surface of an epitaxial wafer.

Embodiments provide an epitaxial growth method capable of controlling the amount of heat supplied to a wafer by adjusting the distance between the wafer and a reflector or the shape of the reflector.

Embodiments provide an epitaxial growth method capable of blocking or dispersing light concentrated on a radial middle part of the wafer at which temperatures are relatively high.

An epitaxial growth method according to an embodiment may include loading a first wafer into a chamber in which a reflector with adjustable position or shape is disposed, seating the first wafer on an upper surface of a susceptor provided in the chamber, growing, by deposition, an epitaxial layer on the surface of the first wafer while supplying heat using a heater disposed above the susceptor, unloading the first wafer with the epitaxial layer deposited thereon out of the chamber, obtaining physical data of the epitaxial layer deposited on the surface of the first wafer using a measurement unit, analyzing, by a controller, quality of the epitaxial layer based on the physical data and calculating an amount of movement or shape deformation of the reflector to be required, displaying information about the required amount of movement or shape deformation of the reflector calculated by the controller through a display unit, and growing, by deposition, an epitaxial layer on the surface of a second wafer newly loaded into the chamber using the reflector with the position or shape adjusted according to the required amount of movement or shape deformation.

In the epitaxial growth method according to the embodiment, the physical data may include at least one of the thickness of the epitaxial layer, roughness of the epitaxial layer, haze of the epitaxial layer, resistivity of the epitaxial layer, and flatness of the epitaxial layer.

In the epitaxial growth method according to the embodiment, the reflector may have a diameter less than the diameter of the heater.

In the epitaxial growth method according to the embodiment, the reflector may be formed in a doughnut shape parallel to the wafer.

In the epitaxial growth method according to the embodiment, the physical data which may be generated based on a value measured at a radial distance of approximately 100 mm from the center of the wafer.

In the epitaxial growth method according to the embodiment, the reflector may be disposed at any one of positions spaced apart from the wafer by 45 mm, 60 mm, 75 mm, and 105 mm.

In the epitaxial growth method according to the embodiment, adjusting the position of the reflector may include disposing the reflector so as to be spaced apart from the wafer by a first distance if the epitaxial layer is thinner on an inner side and thicker on an outer side in a radial direction of the wafer radius and disposing the reflector so as to be spaced apart from the wafer by a second distance larger than the first distance if the epitaxial layer is thicker on the inner side and thinner on the outer side.

An epitaxial growth method according to another embodiment may include loading a wafer into a chamber in which a reflector with adjustable position or shape is disposed, seating the wafer on an upper surface of a susceptor provided in the chamber, growing, by primary deposition, an epitaxial layer on the surface of the wafer while supplying heat using a heater disposed above the susceptor, obtaining temperature data of the epitaxial layer deposited on the surface of the wafer using a measurement unit, analyzing, by a controller, thermal distribution of the wafer based on the temperature data, calculating, by the controller, an amount of movement or shape deformation of the reflector to be required using the result of analysis of the thermal distribution, displaying information about the required amount of movement or shape deformation of the reflector calculated by the controller through a display unit, and growing, by secondary deposition, an epitaxial layer on the surface of the wafer using the reflector with the position or shape adjusted according to the required amount of movement or shape deformation.

In the epitaxial growth method according to the other embodiment, the controller may control the position or shape of the reflector to control the size of light incident onto a middle part of the wafer in a radial direction of the wafer.

In the epitaxial growth method according to the other embodiment, the controller may calculate the required amount of movement or shape deformation of the reflector based on temperature deviation of the surface of the wafer.

### BRIEF DESCRIPTION OF THE DRAWINGS

Arrangements and embodiments may be described in detail with reference to the following drawings in which like reference numerals refer to like elements and wherein:

FIG. 1 is a flowchart showing the steps of a conventional epitaxial manufacturing method;

FIGS. 2A and 2B are flowcharts showing the steps of an epitaxial growth method according to an embodiment;

FIG. 3 is an illustrative view schematically showing an epitaxial growth apparatus for implementing the epitaxial growth method according to the embodiment;

FIGS. 4A and 4B are, respectively, a plan view and a side sectional view showing a reflector applied to the epitaxial growth apparatus shown in FIG. 3;

FIG. 5 is an illustrative view showing the position of a wafer at which measurement is performed and the size of the reflector in the epitaxial growth method according to the embodiment;

FIGS. 6A to 6D are illustrative views showing the states in which the reflector is moved in a vertical direction in the epitaxial growth method according to the embodiment;

FIG. 7 is a flowchart showing the steps of an epitaxial growth method according to another embodiment;

FIG. 8 is an illustrative view schematically showing an epitaxial growth apparatus for implementing the epitaxial growth method according to the other embodiment;

FIG. 9 is a graph showing the epitaxial layer thickness profile according to the height of the reflector in the epitaxial growth method according to the embodiment;

FIG. 10 is a graph showing the intra-wafer variation range according to the width of the reflector to which the epitaxial growth method according to the embodiment is applied;

FIG. 11 is a graph showing the intra-wafer light intensity drop position according to the position of the reflector to which the epitaxial growth method according to the embodiment is applied;

FIG. 12 is a graph showing the intra-wafer temperature distribution in the prior art and the embodiment; and

FIG. 13 is an illustrative view showing an epitaxial growth apparatus according to yet another embodiment.

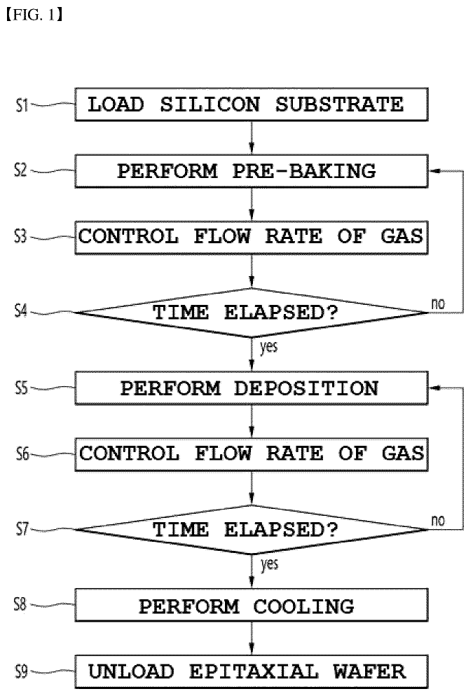

### DESCRIPTION OF SPECIFIC EMBODIMENTS

Specific structural or functional descriptions of embodiments disclosed in this specification are given only for illustrating the embodiments. The embodiments of the present disclosure may be realized in various forms, and should not be interpreted to be limited to the embodiments disclosed in this specification.

Since the embodiments may be variously modified and may have various forms, specific embodiments will be shown in the drawings and will be described in detail in this specification. However, the embodiments are not limited to such specific embodiments, and it should be understood that the embodiments include all alterations, equivalents, and substitutes that fall within the idea and technical scope of the present disclosure.

It will be understood that, although the terms “first”, “second”, etc. may be used herein to describe various elements, corresponding elements should not be understood to be limited by these terms, which are used only to distinguish one element from another. For example, within the scope defined by the present disclosure, a first element may be referred to as a second element, and similarly, a second element may be referred to as a first element.

It will be understood that, when a component is referred to as being “connected to” or “coupled to” another component, it may be directly connected to or coupled to the other component, or intervening components may be present. In contrast, when a component is referred to as being “directly connected to” or “directly coupled to” another component, there are no intervening components present. Other terms that describe the relationship between components, such as “between” and “directly between” or “adjacent to” and “directly adjacent to”, must be interpreted in the same manner.

The terms used in this specification are provided only to explain specific embodiments, but are not intended to restrict the present disclosure. A singular representation may include a plural representation unless it represents a definitely different meaning from the context. It will be further understood that the terms “comprises”, “has” and the like, when used in this specification, specify the presence of stated features, numbers, steps, operations, elements, components or combinations thereof, but do not preclude the presence or addition of one or more other features, numbers, steps, operations, elements, components, or combinations thereof.

Unless otherwise defined, all terms, including technical and scientific terms, used in this specification have the same meanings as those commonly understood by a person having ordinary skill in the art to which the present disclosure pertains. It will be further understood that terms, such as those defined in commonly used dictionaries, should be interpreted as having meanings consistent with their meanings in the context of the relevant art and the present disclosure, and are not to be interpreted in an idealized or overly formal sense unless expressly so defined herein.

Meanwhile, in the case in which a certain embodiment is differently realized, a function or operation specified in a specific block may be performed differently from the sequence specified in a flowchart. For example, two continuous blocks may be substantially simultaneously performed, or the blocks may be performed in reverse order depending on related functions or operations.

Hereinafter, an epitaxial growth method according to an embodiment will be described with reference to the accompanying drawings.

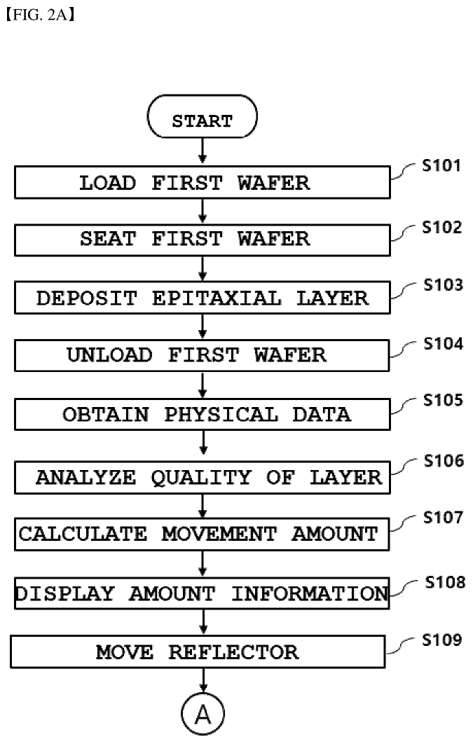

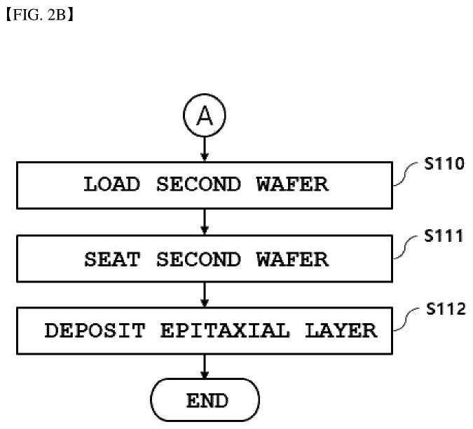

FIGS. 2A and 2B are flowcharts showing the steps of an epitaxial growth method according to an embodiment, and FIG. 3 is an illustrative view schematically showing an epitaxial growth apparatus for implementing the epitaxial growth method according to the embodiment.

The epitaxial growth method according to the embodiment may measure physical data of an epitaxial layer deposited on a first wafer and control the position or shape deformation of a reflector disposed in a chamber accordingly, as shown in the flowchart of FIG. 2A, and may equalize the thickness of an epitaxial layer deposited on the surface of a second wafer introduced into subsequent steps according to new conditions, as shown in the flowchart of FIG. 2B. In the following description, the movement, i.e., the position adjustment, of the reflector may include the movement of the reflector in a vertical direction or a horizontal direction. In addition, the shape deformation of the reflector may include changes in the width or the diameter of the reflector. In the following description, “the amount of movement” refers to the magnitude by which the position of the reflector changes or the magnitude by which the width or diameter of the reflector changes.

The epitaxial growth apparatus 200 for implementing the epitaxial growth method according to the embodiment includes a chamber 210, a susceptor 220, a heater 230, a reflector 240, a measurement unit 251, a controller 260, and a display unit 270.

First, a first wafer 281 is loaded into the chamber 210 in which the reflector 240 with adjustable position or shape is disposed (S101).

The first wafer 281 is seated on an upper surface of the susceptor 220 provided in the chamber 210. The susceptor 220 may be a carbon-based material coated with a SiC film. The first wafer 281 is received in a pocket formed in the susceptor 220 (S102).

The chamber 210 forms a space through which deposition gas for formation of an epitaxial layer on the first wafer 281 flows. Carrier gas and source gas (or feedstock gas or reaction gas) required to grow the epitaxial layer on the surface of the first wafer 281 in the chamber 210 are introduced into the chamber 210 through a gas inlet. The heater 230 is disposed above the susceptor 220 so as to be spaced apart therefrom, is installed along the circumference of the chamber 210, and supplies heat necessary to grow the epitaxial layer on the surface of the first wafer 281. The susceptor 220 with the first wafer 281 seated on an upper surface thereof rotates during epitaxial layer deposition. Once the epitaxial layer is formed on the surface of the first wafer 281 in the chamber 210, the gases contributing to reaction may be discharged through a gas outlet. To this end, the gas inlet and the gas outlet may be formed opposite each other. At this time, the reflector 240 may reflect a part of the light emitted from the heater 230 to prevent concentration of the light on a radial middle part of the first wafer 281 placed on the susceptor 220.

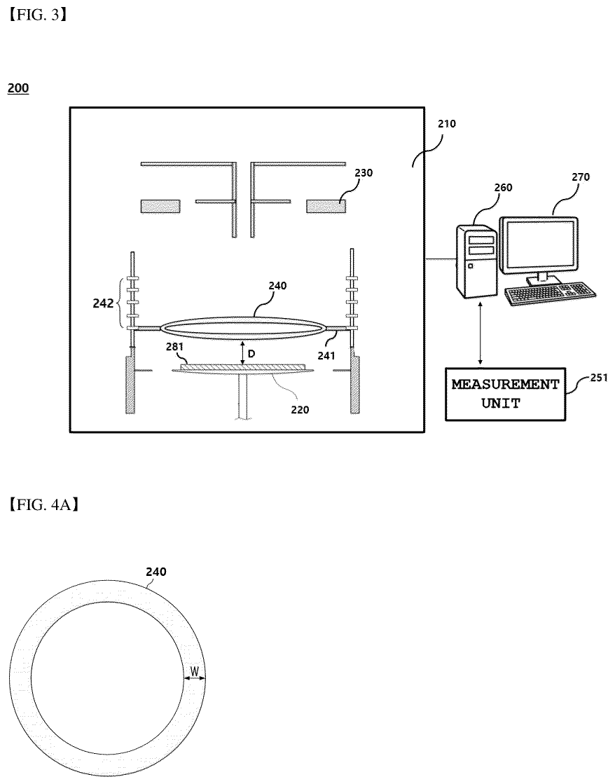

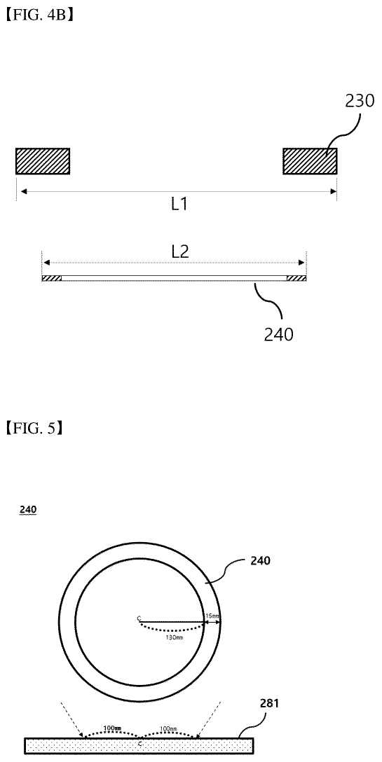

As shown in FIGS. 4A and 4B, the reflector 240 may have a doughnut shape and be installed parallel to the heater 230. The reflector may be mounted by being hung from a peripheral structure so as to be parallel to the susceptor 220 and the first wafer 281 by separate wires, but the present disclosure is not limited thereto. Preferably, the width of the reflector 240 is 10 mm to 20 mm, which is according to the embodiment, and the present disclosure is not limited thereto. The diameter L2 of the reflector 240 is less than the diameter L1 of the heater 230. The radial width W of the reflector 240 and the installation position of the reflector 240 may be set differently depending on the in-plane light intensity distribution of the susceptor 220 or the first wafer 281 (S103).

Upon completion of deposition, the first wafer 281 is unloaded from the chamber 210 (S104).

The first wafer 281 is located at the measurement unit 251 located outside the chamber 210, and the controller 260 provides a control signal for initiating measurement to the measurement unit 251. Data exchange between the controller 260 and the measurement unit 251 may be performed wirelessly or via wired connections. The controller 260 may be implemented by a computer. The measurement unit 251 obtains physical data of the epitaxial layer deposited on the surface of the first wafer 281 according to the received control signal.

As shown in FIG. 5, the measurement unit 251 generates physical data based on values measured at a radial distance of 100 mm from the center of the first wafer 281. The reflector 240 has a width of 15 mm at a radius between 130 mm and 145 mm. The physical data measured by the measurement unit 251 may include at least one of the thickness of the epitaxial layer, roughness of the epitaxial layer, haze of the epitaxial layer, resistivity of the epitaxial layer, and flatness of the epitaxial layer (S105).

The measurement unit 251 provides the obtained physical data to the controller 260. The controller 260 analyzes the quality of the epitaxial layer based on the received physical data. That is, the controller determines whether the epitaxial layer is uniformly deposited on the surface of the wafer, measures the amounts of impurities determining electrical characteristics, or analyzes the composition ratio of elements included in the epitaxial layer. Since the embodiment aims to maintain a uniform thickness of the epitaxial layer deposited on the surface of the wafer, the controller 260 performs quality analysis of the epitaxial layer using the thickness profile, uniformity, surface roughness, resistivity, and flatness of the epitaxial layer (S106).

The controller 260 calculates the required amount of movement or shape deformation of the reflector 240 using the quality analysis results. For example, the controller 260 controls the reflector to be located away from the wafer by a first distance if the epitaxial layer is thinner on an inner side and thicker on an outer side in a radial direction of the wafer, and controls the reflector to be located away from the wafer by a second distance larger than the first distance if the epitaxial layer is thicker on the inner side and thinner on the outer side. Specifically, if the movement of the reflector 240 is required, the controller 260 calculates the amount of movement of the reflector 240 such that, if the epitaxial layer is thinner on an inner side and thicker on an outer side based on a wafer radius of 100 mm based on the analysis results, the reflector is located 45 mm to 60 mm away from the wafer 280. The controller 260 calculates the amount of movement of the reflector 240 such that, if the epitaxial layer is thicker on the inner side and thinner on the outer side based on a wafer radius of 100 mm based on the analysis results, the reflector 240 is located 60 mm to 105 mm away from the wafer 280(S107).

The controller 260 displays information about the calculated amount of movement of the reflector 240 through the display unit 270. In this embodiment, a monitor configured to visually display the information about the amount of movement of the reflector 240 to an operator is shown as an example; however, in some cases, the information about the amount of movement of the reflector may also be provided to the operator as an audio signal using a speaker (S108).

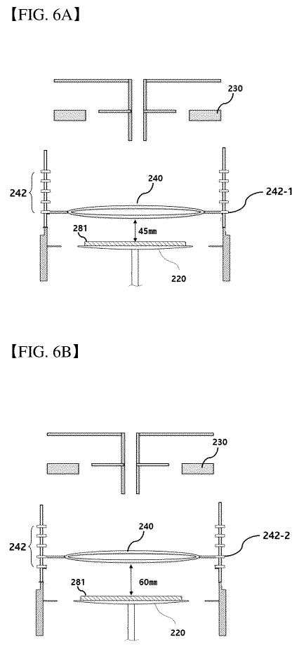

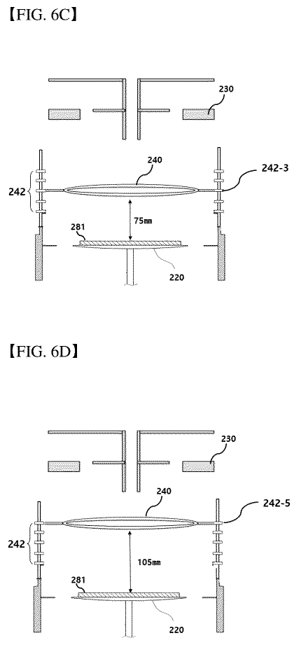

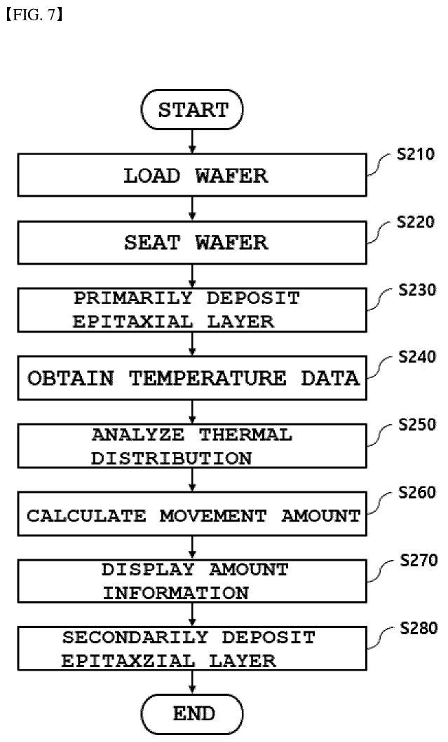

The position or size of the reflector 240 is changed based on information about the required amount of movement or shape deformation of the reflector calculated by the controller 260. FIGS. 6A to 6D show that the reflector 240 is disposed at various positions based on the data calculated by the controller 260 of the epitaxial growth apparatus for implementing the epitaxial growth method according to the embodiment.

FIG. 6A shows the state in which the reflector 240 is fixed to a reflector fixture 242-1 so as to be spaced apart from the wafer 280 by 45 mm. FIG. 6B shows the state in which the reflector 240 is fixed to a reflector fixture 242-2 so as to be spaced apart from the wafer 280 by 60 mm. FIG. 6C shows the state in which the reflector 240 is fixed to a reflector fixture 242-3 so as to be spaced apart from the wafer 280 by 75 mm. FIG. 6D shows the state in which the reflector 240 is fixed to a reflector fixture 242-5 so as to be spaced apart from the wafer 280 by 105 mm. A reflector fixture 242 is shown as being configured such that the respective fixtures 242-1 to 242-5 are disposed at intervals of 15 mm, but this is one embodiment and the present disclosure is not limited thereto. If the inner side of the epitaxial layer is measured to be thinner and the outer side of the epitaxial layer is measured to be thicker, the reflector 240 is disposed so as to be spaced apart from the surface of the wafer 280 by 45 mm to 60 mm such that the inner side becomes thicker and the outer side becomes thinner, as shown in FIG. 6A or 6B. Conversely, if the inner side of the epitaxial layer is measured to be thicker and the outer side of the epitaxial layer is measured to be thinner, the reflector 240 is disposed so as to be spaced apart from the surface of the wafer 280 by 60 mm to 105 mm such that the inner side becomes thinner and the outer side becomes thicker, as shown in FIGS. 6B to 6D (S109).

After the reflector 240 is moved according to the quality analysis results based on the physical data of the epitaxial layer deposited on the surface of the first wafer 281, as described with reference to FIG. 2A, an epitaxial layer is grown on the surface of the first wafer 281 with the position of the reflector adjusted, as shown in the flowchart240 of FIG. 2B.

A second wafer 281, that is, a wafer intended for mass production, is loaded into the chamber 210 in which the position or shape of the reflector 240 has been adjusted (S110). The second wafer 281 refers to a wafer, newly loaded, which is different from the first wafer 281 in FIG. 2A.

The second wafer 281 is seated on the upper surface of the susceptor 220 provided in the chamber 210 (S111).

Subsequently, gas is introduced into the chamber, heat is supplied to the heater, and an epitaxial layer is grown on the surface of the second wafer 281 (S112).

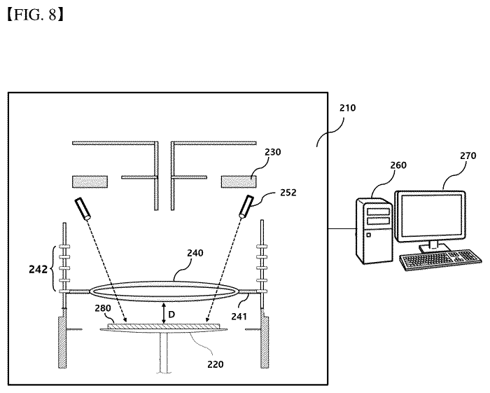

FIG. 7 is a flowchart showing the steps of an epitaxial growth method according to another embodiment. FIG. 8 is an illustrative view schematically showing an epitaxial growth apparatus for implementing the epitaxial growth method according to the other embodiment.

In the epitaxial growth method according to the other embodiment, a wafer is not unloaded outside a chamber to measure the temperature of an epitaxial layer deposited on the wafer, unlike the epitaxial growth method according to the embodiment described with reference to FIGS. 2A and 2B.

The epitaxial growth apparatus 200 for implementing the epitaxial growth method according to the other embodiment includes a chamber 210, a susceptor 220, a heater 230, a reflector 240, a measurement unit 252, a controller 260, and a display unit 270.

The epitaxial growth method according to the other embodiment is different from the epitaxial growth method according to the embodiment shown in FIGS. 2A and 2B in that thermal distribution of the epitaxial layer is analyzed to change the position of the reflector.

A wafer 280 is loaded into the chamber 210 in which the reflector 240 with adjustable position is disposed (S210). The wafer 280 loaded into the chamber 210 is received in a pocket formed in the susceptor 220 (S220). A primary epitaxial layer is grown on the surface of the wafer 280 while supplying heat using the heater 230 located above the susceptor 220 (S230). Temperature data of the epitaxial layer deposited on the surface of the wafer 280 is obtained using the measurement unit 252 (S240). The temperature data obtained by the measurement unit 252 is provided to the controller 260.

The controller 260 analyzes thermal distribution in the wafer based on the temperature data (S250). The controller 260 calculates the required amount of movement or shape deformation of the reflector 240 using the results of thermal distribution analysis. At this time, the controller 260 controls the position (or size) of the reflector 240 to control the size of the light incident onto a radial middle part of the wafer 280. That is, the controller 260 calculates the required amount of movement or shape deformation of the reflector 240 based on the temperature deviation of the surface of the wafer 280 (S260).

The display unit 270 displays information about the required amount of movement or shape deformation of the reflector 240 calculated by the controller 260 (S270).

When the position of the reflector 240 is changed, the reflector 240 is spaced apart from the wafer by the calculated amount of movement. For example, the reflector 240 may be disposed so as to be spaced apart from the wafer by 45 mm, 60 mm, 75 mm, or 105 mm. Meanwhile, when the shape of the reflector 240 is deformed, a reflector with a width or diameter different from that of the current reflector by the required amount of shape deformation is used.

This is according to the embodiment, and the present disclosure is not limited thereto. An epitaxial layer is secondarily grown on the surface of the wafer using the reflector 240 with position or size adjusted as described above (S280).

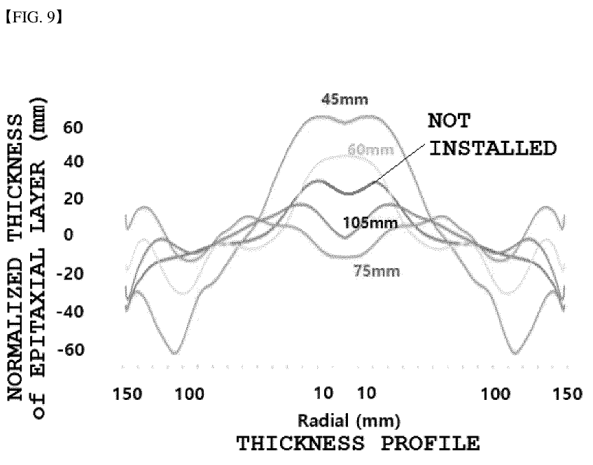

FIG. 9 is a graph showing the epitaxial layer thickness profile according to the height of the reflector in the epitaxial growth method according to the embodiment. The horizontal axis indicates the distance from the center to the periphery of the wafer, and the vertical axis indicates the normalized thickness of the epitaxial layer. The difference between the epitaxial layer thickness at each position and the average thickness of the entire epitaxial layer when the position of the reflector is varied from 45 mm to 105 mm is shown. That is, when the reflector is spaced apart from the surface of the wafer by 45 mm, the difference between the thickness of the epitaxial layer at a distance of approximately 10 mm from the center of the wafer and the average thickness of the entire epitaxial layer is approximately 60 nm. When the reflector is spaced apart from the surface of the wafer by 60 mm, the difference between the thickness of the epitaxial layer at a distance of approximately 10 mm from the center of the wafer and the average thickness of the entire epitaxial layer is approximately 40 nm. When the reflector is spaced apart from the surface of the wafer by 105 mm, the difference between the thickness of the epitaxial layer at a distance of approximately 10 mm from the center of the wafer and the average thickness of the entire epitaxial layer is approximately 20 nm. When the reflector is spaced apart from the surface of the wafer by 75 mm, the difference between the thickness of the epitaxial layer at a distance of approximately 10 mm from the center of the wafer and the average thickness of the entire epitaxial layer is approximately −10 nm.

Meanwhile, when the reflector is spaced apart from the surface of the wafer by 45 mm, the difference between the thickness of the epitaxial layer at a distance of approximately 100 mm from the center of the wafer and the average thickness of the entire epitaxial layer is approximately −60 nm. When the reflector is spaced apart from the surface of the wafer by 60 mm, the difference between the thickness of the epitaxial layer at a distance of approximately 100 mm from the center of the wafer and the average thickness of the entire epitaxial layer is approximately −30 nm. When the reflector is spaced apart from the surface of the wafer by 105 mm, the difference between the thickness of the epitaxial layer at a distance of approximately 100 mm from the center of the wafer and the average thickness of the entire epitaxial layer is approximately −5 nm. When the reflector is spaced apart from the surface of the wafer by 75 mm, the difference between the thickness of the epitaxial layer at a distance of approximately 100 mm from the center of the wafer and the average thickness of the entire epitaxial layer is approximately −10 nm.

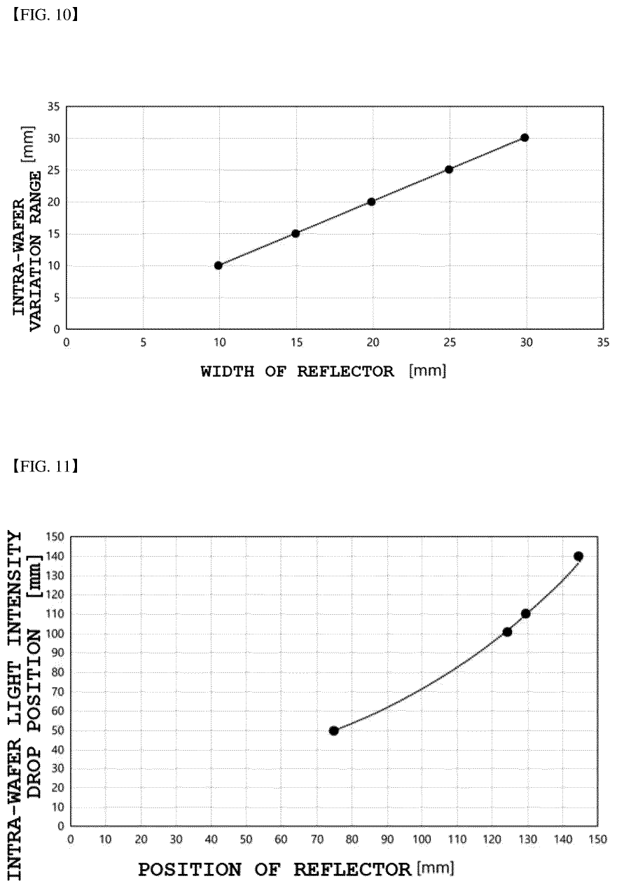

FIG. 10 is a graph showing the intra-wafer variation range according to the width of the reflector applied to the embodiment, and FIG. 11 is a graph showing the intra-wafer light intensity drop position according to the position of the reflector applied to the embodiment.

As shown in FIG. 10, it can be seen that, as the width of the reflector applied to the embodiment increases, the intra-wafer temperature variation range also increases. Therefore, it is desirable to configure the width of the reflector to be equal to the width of the intra-wafer hot spot.

As shown in FIG. 11, as the position of the reflector applied to the embodiment increases in a radial direction, the intra-wafer light intensity drop position also increases in the radial direction. Since the reflector is located farther inward than the heater, it can be seen that the intra-wafer light intensity drop position in the radial direction appears farther inward than the position of the reflector in the radial direction. That is, it is desirable for the position of the reflector in the radial direction to be located at a predetermined distance outward from the intra-wafer hot spot.

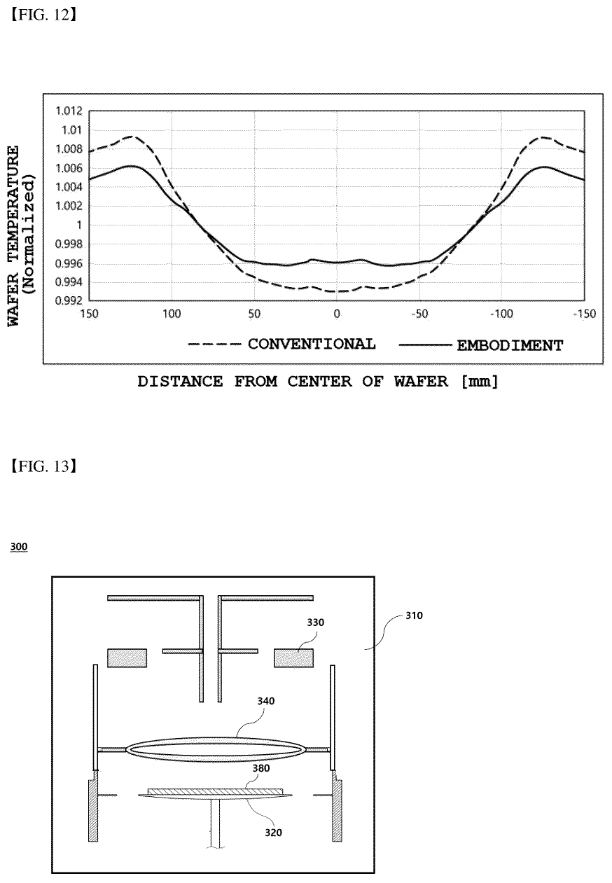

FIG. 12 is a graph showing the intra-wafer temperature distribution in the prior art and the embodiment. In the embodiment, the doughnut-shaped reflector with adjustable position is provided between the heater and the wafer, compared to the prior art. Consequently, light concentrated on the radial middle part of the wafer at which temperatures are relatively high may be blocked or dispersed by controlling the distance between the reflector and the heater based on the measured thickness of the currently deposited epitaxial layer, and therefore it is possible to reduce the intra-wafer temperature variation and to achieve a more uniform thickness of the epitaxial layer deposited across the entire wafer.

FIG. 13 is an illustrative view showing an epitaxial growth apparatus according to yet another embodiment.

As shown in FIG. 13, the epitaxial growth apparatus 300 according to the yet another embodiment may include a chamber 310 through which deposition gas flows, a susceptor 320 provided in the chamber 310, the susceptor having an upper surface on which a wafer 380 is seated, a heater 330 disposed above the susceptor 320, the heater being configured to supply heat necessary to grow an epitaxial layer to the surface of the wafer 380, and a doughnut-shaped reflector 340 disposed between the heater 330 and the susceptor 320.

Unlike the embodiments of FIGS. 3 and 8, the reflector 340 may be fixed in the chamber 310. The description given with reference to FIGS. 4A and 4B applies to the shape and size of the reflector and the relationship between the reflector and the heater.

As is apparent from the above description, the epitaxial growth method according to the embodiment may have the effect of depositing an epitaxial layer having a uniform thickness on the surface of a wafer by varying the position of the reflector and controlling the amount of heat supplied to the wafer.

Although the present disclosure has been described above with reference to exemplary embodiments, those skilled in the art will understand that the present disclosure can be modified and changed in various ways without departing from the spirit and scope of the disclosure as defined in the appended claims.

What is claimed is:

1. An epitaxial growth method, comprising:
loading a first wafer into a chamber in which a reflector with adjustable position or shape is disposed;
seating the first wafer on an upper surface of a susceptor provided in the chamber;
growing, by deposition, an epitaxial layer on a surface of the first wafer while supplying heat using a heater disposed above the susceptor;
unloading the first wafer with the epitaxial layer deposited thereon out of the chamber;
obtaining physical data of the epitaxial layer deposited on the surface of the first wafer using a measurement unit;
analyzing, by a controller, quality of the epitaxial layer based on the physical data and calculating an amount of movement or shape deformation of the reflector to be required;
displaying information about the required amount of movement or shape deformation of the reflector calculated by the controller through a display unit; and
growing, by deposition, an epitaxial layer on a surface of a second wafer newly loaded into the chamber using the reflector with the position or shape adjusted according to the required amount of movement or shape deformation.

2. The epitaxial growth method according to claim 1, wherein the physical data includes at least one of a thickness profile of the epitaxial layer, roughness of the epitaxial layer, haze of the epitaxial layer, resistivity of the epitaxial layer, and flatness of the epitaxial layer.

3. The epitaxial growth method according to claim 1, wherein the reflector has a diameter less than a diameter of the heater.

4. The epitaxial growth method according to claim 1, wherein the reflector is formed in a doughnut shape parallel to the wafer.

5. The epitaxial growth method according to claim 4, wherein the physical data is generated based on a value measured at a radial distance of approximately 100 mm from a center of the wafer.

6. The epitaxial growth method according to claim 5, wherein the reflector is disposed at any one of positions spaced apart from the wafer by 45 mm, 60 mm, 75 mm, and 105 mm.

7. The epitaxial growth method according to claim 4, wherein adjusting the position of the reflector includes:
disposing the reflector so as to be spaced apart from the wafer by a first distance if the epitaxial layer is thinner on an inner side and thicker on an outer side in a radial direction of the wafer; and
disposing the reflector so as to be spaced apart from the wafer by a second distance larger than the first distance if the epitaxial layer is thicker on the inner side and thinner on the outer side.

8. An epitaxial growth method, comprising:
loading a wafer into a chamber in which a reflector with adjustable position or shape is disposed;
seating the wafer on an upper surface of a susceptor provided in the chamber;
growing, by primary deposition, an epitaxial layer on a surface of the wafer while supplying heat using a heater disposed above the susceptor;
obtaining temperature data of the epitaxial layer deposited on the surface of the wafer using a measurement unit;
analyzing, by a controller, thermal distribution of the wafer based on the temperature data;
calculating, by the controller, an amount of movement or shape deformation of the reflector to be required using a result of analysis of the thermal distribution;
displaying information about the required amount of movement or shape deformation of the reflector calculated by the controller through a display unit; and
growing, by secondary deposition, an epitaxial layer on the surface of the wafer using the reflector with the position or shape adjusted according to the required amount of movement or shape deformation.

9. The epitaxial growth method according to claim 8, wherein the controller controls the position of the reflector to control a size of light incident onto a middle part of the wafer in a radial direction of the wafer.

10. The epitaxial growth method according to claim 8, wherein the controller calculates the required amount of movement or shape deformation of the reflector based on temperature deviation of the surface of the wafer.
